(19) United States
(12) Patent Application Publication
(10) Pub. No.: US 2022/0155118 A1
(43) Pub. Date: May 19, 2022

(54) Flowmeter, Sensor Unit and Method for Manufacturing a Flowmeter

(71) Applicant: KROHNE AG, Basel (CH)

(72) Inventors: Jacco Elenbaas, Heijningen (NL); Gijs Braanker, Dordrecht (NL)

(21) Appl. No.: 17/455,794

(22) Filed: Nov. 19, 2021

(30) Foreign Application Priority Data
Nov. 19, 2020 (DE) 102020130596.6

(51) Int. Cl. G01F 1/684; H05K 1/02; G01F 1/56; G01F 1/34

(52) U.S. Cl. CPC G01F 1/684; H05K 1/028; H05K 2201/10151; G01F 1/34; G01F 1/56

(57) ABSTRACT

A flowmeter includes at least one measuring tube, a measuring arrangement for measuring the flow of a medium flowing through the measuring tube, at least one receiving unit for a sensor unit and a sensor unit. The receiving unit is arranged on the measuring tube. The sensor unit includes at least one sensor, at least one flexible printed circuit board and at least one carrier. The at least one sensor is arranged on the at least one flexible printed circuit board. The sensor unit is plugged into the receiving unit. The at least one flexible printed circuit board is at least partially wrapped or folded around the carrier such that the sensor is arranged inside the measuring tube in the inserted state.

### TECHNICAL FIELD

The invention is based on a flowmeter with at least one measuring tube, with a measuring arrangement for measuring the flow of a medium flowing through the measuring tube, with at least one receiving unit for a sensor unit and with a sensor unit, wherein the receiving unit is arranged on the measuring tube. In addition, the invention relates to a sensor unit for installation in a flowmeter according to the invention, with at least one sensor, with at least one flexible printed circuit board and with at least one carrier, as well as a method for manufacturing a flowmeter according to the invention.

### BACKGROUND

In some applications, it is advantageous that a flowmeter has at least one further sensor unit for measuring at least one further parameter in addition to the actual measuring unit for determining the flow. In these cases, the at least one additional sensor unit has to be arranged or placed on or in the measuring tube such that the additional sensor can, on the one hand, reliably measure the parameter to be measured and, on the other hand, can be easily installed and removed.

A measuring device with an electronic unit is known from the document DE 10 2011 119 841 A1, wherein the electronic unit comprises a flexible printed circuit board on which at least two rigid contact pins are soldered such that one end of the contact pins protrudes over the flexible printed circuit board and wherein the flexible printed circuit board is formed into a three-dimensional body by folding and/or bending, wherein the body is held in its three-dimensional form by means of a foldable carrier. In addition, a sensor can also be soldered to the flexible printed circuit board, wherein the printed circuit board is bent so that the sensor is positioned in the desired position within the measuring device.

### SUMMARY

Based on this state of the art, the object of the invention to provide a flowmeter with an additional sensor unit which can be arranged and exchanged particularly easily. In addition, the object of the invention is to provide a sensor unit which can be particularly easily arranged and exchanged in a flowmeter according to the state of the art and a method for manufacturing a flowmeter.

According to a first teaching of the present invention, the aforementioned object is achieved by a flowmeter mentioned at the beginning in that the sensor unit comprises at least one sensor, at least one flexible printed circuit board and at least one carrier,
wherein the at least one sensor is arranged on the at least one flexible printed circuit board and
that the sensor unit is plugged into the receiving unit,
wherein the at least one flexible printed circuit board is at least partially wrapped or folded around the carrier such that the sensor is arranged within the measuring tube in the inserted state.

According to the invention, it was recognized that the connection of a flexible printed circuit board to a carrier is advantageous in that the printed circuit board can be at least partially adapted to the shape of the carrier. The mounting of the sensor unit can thus be carried out in an advantageous way by mounting the carrier, wherein the carrier is only inserted into the receiving unit. At the same time, the sensor, which is arranged on the flexible printed circuit board, is thereby placed in the measuring tube for measuring at least one additional parameter.

Because the flexible printed circuit board is only wrapped or folded around the carrier, a complex installation and mounting of the printed circuit board or the additional sensor can be avoided.

If it is said that the sensor unit or the sensor is placed exchangeably in the flowmeter, it is meant that neither the sensor unit nor the sensor in the flowmeter is bonded, in particular glued. The sensor and/or the sensor unit are therefore only arranged in the flowmeter via positive and/or non-positive connections.

The advantage of this arrangement according to the invention is that it is particularly easy to install and the sensor can be easily replaced.

According to a first design, the receiving unit is cup-shaped and the carrier of the sensor unit is at least partially plug-shaped, so that the carrier acts as a plug to close the cup-shaped receiving unit.

It is particularly preferred that the plug-shaped sensor unit is held in the cup-shaped receiving unit by a frictional connection, so that the sensor unit is fixed in place even in case of vibrations and cannot slip out.

It is especially preferred that the at least one sensor is a temperature sensor and/or a pressure sensor and/or a conductivity sensor.

For example, by arranging a conductivity sensor in the measuring tube during operation, it can be determined whether the measuring tube is completely or only partially filled with the medium to be measured.

The flexible printed circuit board is, for example, a bendable printed circuit board, in particular a flex foil, or a rigid-flexible printed circuit board or a semi-flexible printed circuit board. The bendable printed circuit board is completely bendable, i.e. it can be bent at any point. Such a design is advantageous in that the flexible printed circuit board can be wrapped or folded particularly flexibly around the carrier. In addition, the flexible printed circuit board can also be designed as a rigid-flexible printed circuit board or as a semi-flexible printed circuit board. In this case the flexible printed circuit board has rigid areas which are connected by flexible areas. According to this design, the circuit board is wrapped or folded over the bendable areas around the carrier.

According to a further preferred design, the flexible printed circuit board encloses the carrier at least partially in the longitudinal direction and/or at least partially transverse to the longitudinal direction. According to this design the carrier has a longitudinal axis. Especially when the flexible printed circuit board encloses the carrier at least partly in the longitudinal direction and at least partly transverse to the longitudinal direction, the printed circuit board is arranged sturdily around the carrier.

It is particularly preferred that the carrier is of polyamide. According to a further design, the carrier additionally has at least partially a layer comprising an adhesive and/or comprising electrolytic copper. Preferably, a plurality of additional layers is present, in particular comprising an adhesive and/or electrolytic copper.

According to a next design, the carrier has at least one first recess and the flexible printed circuit board has at least one first connection area, wherein preferably the shape of the first recess essentially corresponds to the shape of the first connection area and wherein the flexible printed circuit board is placed with the first connection area into the first recess. Because the flexible printed circuit board with the connection area is inserted into the first recess preferably with a perfect fit, it is held by the carrier at least such that the flexible printed circuit board cannot slip during insertion into the receiving unit.

Particularly preferably, the carrier has at least a first and a second recess, wherein the printed circuit board has at least a first and a second connection area, and wherein the printed circuit board is arranged with the first connection area in the first recess and with the second connection area in the second recess.

According to a next design, the carrier has a recess substantially corresponding to the shape of the contact surface of the flexible printed circuit board with the carrier so that the flexible printed circuit board is held continuously to the carrier at least by the edges of the recess.

According to the next design, the carrier has at least one fixing element for fixing the circuit board on the carrier.

It is particularly preferred that the at least one fixing element is a slot and/or a groove and/or a seam and/or a chamfer and/or an edge protruding, preferably obliquely, beyond the printed circuit board.

An edge protruding obliquely beyond the printed circuit board forms an acute angle, preferably between 45° and 90°, with the receiving surface of the carrier. It is especially preferred that the carrier has at least two edges that protrude obliquely from the printed circuit board and that are arranged opposite to each other.

According to a next design, the flexible printed circuit board has at least one mounting element, preferably in the connection area, wherein the at least one mounting element is preferably in operative connection with the at least one fixing element.

For example, the mounting element is designed as a projection which is arranged in the fixing element so that the printed circuit board is held on the carrier with a positive fit at least in one spatial direction. For example, the projection can be designed and arranged such that it is bent or pushed into the fixing element for fixing.

The fixing of the printed circuit board is particularly preferred by combining the at least one fixing element and the at least one mounting element such that the printed circuit board is fixed in three spatial directions.

According to another preferred design, a ground connection is arranged on the flexible printed circuit board, wherein the ground connection is connected to the housing of the flowmeter. It is particularly preferred that the ground connection is on a second connection area of the flexible printed circuit board, wherein the second connection area is arranged to fit, preferably essentially exactly, in the second recess of the carrier.

According to a next preferred design, the flexible printed circuit board has several functional subsections, wherein the functional subsections are arranged on different arms of the flexible printed circuit board, such that the functional subsections are positioned at the point of their connection by separately bending of the arms.

A first subsection is designed for connection to the carrier. A second subsection is designed for the connection to the measuring arrangement. A third subsection is designed for connection to the power supply. In this subsection, a plug is connected particularly preferably to the printed circuit board.

According to a further preferred design a cover element is arranged on the sensor. The cover element is preferably designed as an insulation element to insulate the sensor. Alternatively or additionally, the cover element has a high thermal conductivity, so that in the case in which the sensor is designed as temperature sensor, a fast response time of the temperature sensor can be guaranteed. According to one design, the cover element has at least two layers, wherein at least one layer is conductive and wherein at least one layer is non-conductive. Particularly preferably, the non-conductive, insulating layer is thinner, in particular much thinner, than the conductive layer. According to one embodiment, the non-conductive layer is a polyamide layer.

According to a further preferred design, the sensor unit is positively and/or non-positively held in the receiving unit. For this, the sensor unit is preferably pressed into the receiving unit.

According to a second teaching of the present invention, the object described above is achieved by a sensor unit described above for installation in a flowmeter according to the invention in that the at least one sensor is arranged on the at least one flexible printed circuit board, wherein the at least one flexible printed circuit board is at least partially wrapped or folded around the carrier.

The sensor unit according to the invention has the advantage that the installation of the sensor can be carried out particularly easily, on the one hand, because the sensor unit only has to be inserted into the receiving unit and, on the other hand, the sensor can be easily exchanged.

It is particularly preferred that the sensor unit is designed according to one of the designs described above.

According to a third teaching of the present invention, the object mentioned above is thereby achieved by a method for manufacturing a flowmeter described above,
in that at least one flexible printed circuit board is first wrapped and/or folded at least partially around the carrier, and
that the sensor unit is then plugged into the receiving unit so that the sensor is arranged inside the measuring tube.

The advantage of this method is that the sensor unit is simply plugged in for mounting and correctly positioning the additional sensor.

### BRIEF DESCRIPTION OF THE DRAWINGS

There is now a plurality of possibilities for designing and further developing the flowmeter, the sensor unit and the method according to the invention. For this, reference is made to the following description of preferred embodiments in conjunction with the drawings.

FIG. 1 illustrates an embodiment of a sensor unit in the unconnected state.

FIG. 2 illustrates an embodiment of a sensor unit according to the invention, with the flexible printed circuit board folded around the carrier.

FIG. 3 illustrates the embodiment shown in FIG. 2 in another view.

FIG. 4 illustrates a further embodiment of a sensor unit according to the invention.

FIG. 5 illustrates a further embodiment of a sensor unit according to the invention.

FIG. 6 illustrates the connection of a sensor unit according to the invention to a measuring tube of a flowmeter.

FIG. 7 illustrates an embodiment of a flowmeter according to the invention.

FIG. 8 illustrates an embodiment of a flexible printed circuit board.

FIG. 9 illustrates a further embodiment of a sensor unit according to the invention.

FIG. 10 illustrates an embodiment of a method for manufacturing a flowmeter.

### DETAILED DESCRIPTION

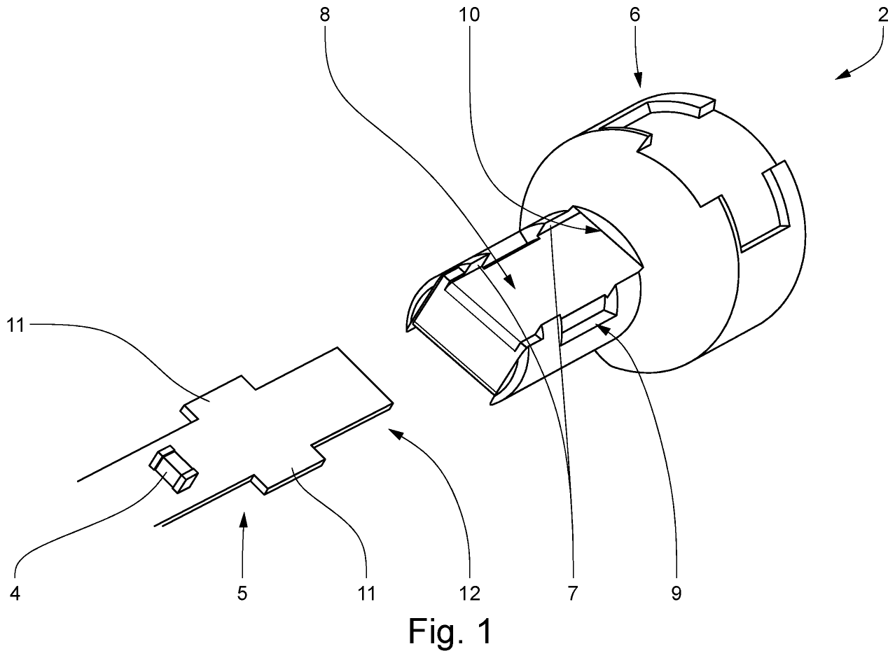

FIG. 1 shows a first embodiment of a sensor unit 2. The sensor unit 2 comprises a sensor 4, which is arranged on a flexible printed circuit board 5, and a carrier 6 to accommodate the flexible printed board 5. In the embodiment shown, the sensor 4 is designed as a temperature sensor. Alternatively, the sensor 4 can, of course, also be designed as a pressure sensor or as a conductivity sensor.

The illustration shows the sensor unit 2 in an unconnected state, i.e. the flexible printed circuit board 5 is not arranged directly on the carrier 6. The printed circuit board 5 has a connection area 12 for connection to the carrier 6. To accommodate the printed circuit board 5, the carrier 6 has an intake area 8 into which the connection area 12 can be inserted.

To fix the printed circuit board 5 on the carrier 6, the carrier has fixing elements in the form of edges 7. For better fixation, the edges can also form an acute angle between 45 and 90° with the receiving surface of the carrier 6. For connection to the carrier, the printed circuit board 5 can thus be inserted into the intake area 8 of the carrier 6 and fixed by the edges 7 protruding beyond the printed circuit board 5. Furthermore, the carrier 6 has a slot 10 in the intake area 8 for fixing into which the printed circuit board 5 can be inserted.

In addition, the carrier 6 has two chamfers 9 in the area of the receiving area for further fixation. For connection, the printed circuit board 5 has mounting elements in the form of lateral projections 11 which can be folded into the chamfers 9 when connected.

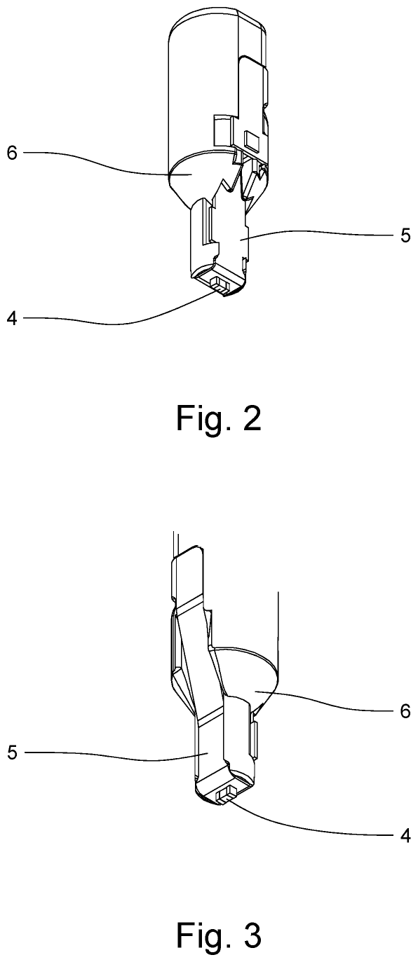

FIG. 2 shows an embodiment of a sensor unit 2 with the flexible printed circuit board 5 bent around the carrier 6, such that the printed circuit board 5 can be mounted with the carrier 6. In this arrangement, the sensor 4 is arranged below the plug-like carrier 6 so that the sensor 4 can be placed in the measuring tube 17 by inserting it into the receiving unit 16 of a measuring tube 17.

FIG. 3 shows the embodiment of a sensor unit 2 as shown in FIG. 2 in a rotated view. The illustration shows that, in addition to the printed circuit board 5 being fixed in the first connection area 12, the printed circuit board 5 is also fixed to the carrier 6 by edges on the side opposite to the first connection area 12. This ensures that the printed circuit board 5 lies flat against the carrier 6.

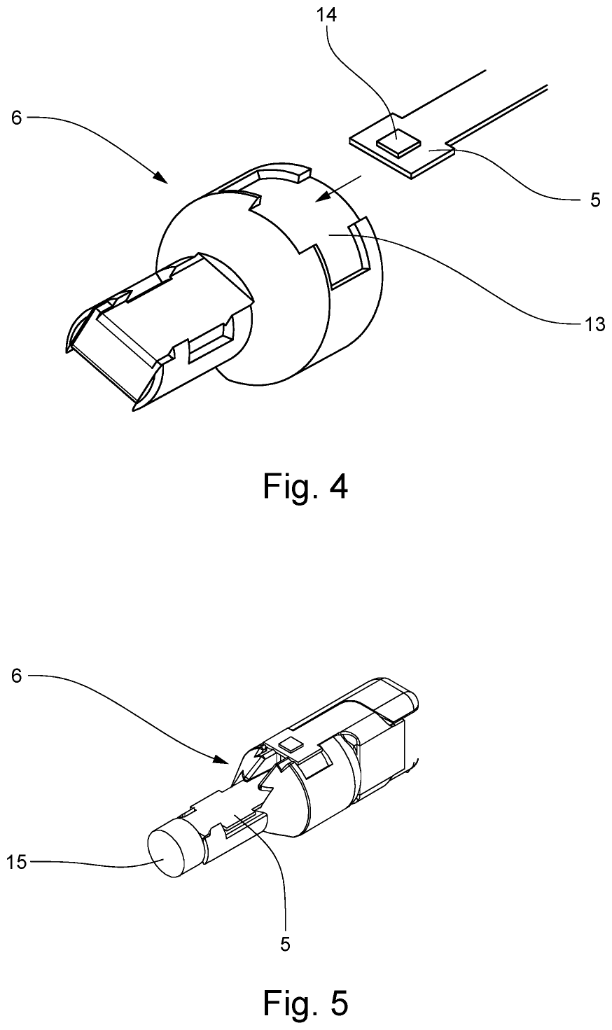

FIG. 4 shows a further embodiment of a sensor unit 2, wherein the carrier 6 has a further intake area in Form of a recess 13 to accommodate a further functional part of the printed circuit board 5, wherein the corresponding connection area of the printed circuit board 5 is designed such that it can be inserted into the recess 13. The connection area is held in the recess 13 of the carrier 6 by stops. On the connection area of the printed circuit board 5, there is a ground connection 14, which is designed for connection to the housing when the carrier 6 is inserted.

FIG. 5 shows an example of a sensor unit 2 in which the printed circuit board 5 is folded around the longitudinal axis of the carrier 6. A cover element 15 is arranged on the sensor 4. This cover element 15 is used to insulate the sensor 4 during operation. In addition, the cover element 15 has a high thermal conductivity so that the response time of the sensor 4, which is designed as a temperature sensor in the embodiment shown, is particularly high during operation.

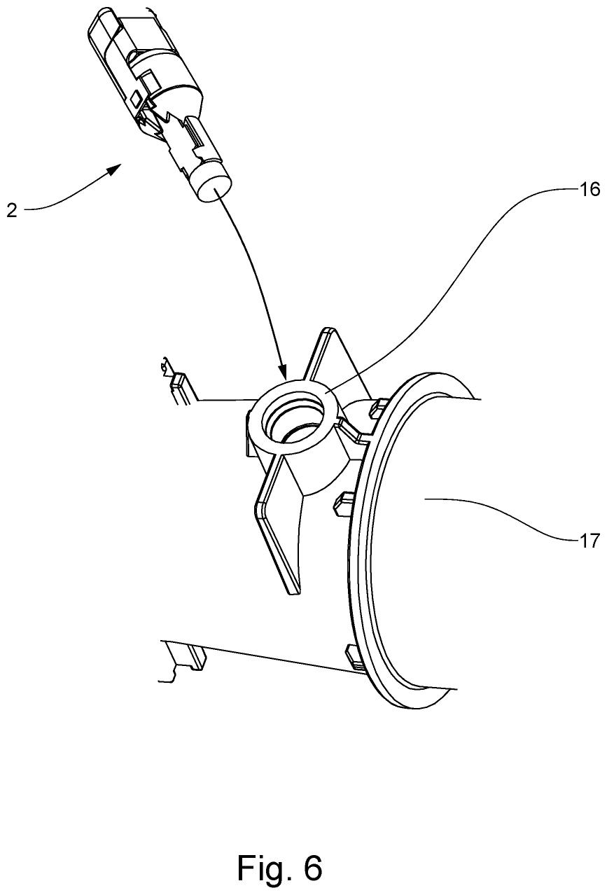

FIG. 6 shows a combination of the sensor unit 2 shown in FIG. 5 and a cup-shaped receiving unit 16 for the sensor unit 2. The receiving unit 16 is arranged on a measuring tube 17 of a flowmeter 1. The illustration shows that the sensor unit 2 is designed such that it only needs to be inserted into the receiving unit 16 for connection to the flowmeter 1 and thus for placement of the sensor 4. In the receiving unit 16, the sensor unit 2 is then held non-positively in place so that, at the same time, the sensor unit can be replaced very easily.

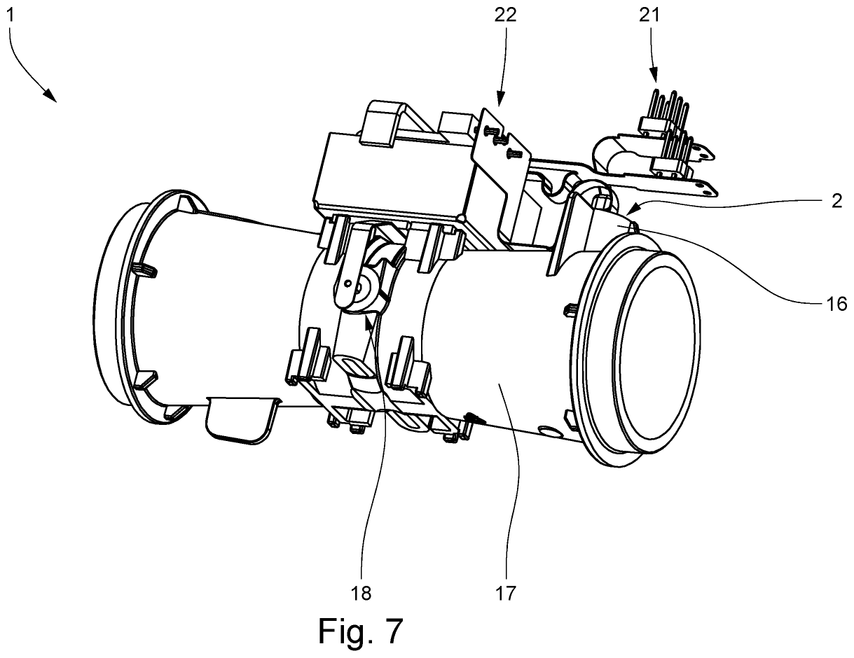

FIG. 7 shows an embodiment of a flowmeter 1 in the form of an electromagnetic flowmeter, comprising a measuring tube 17, a measuring arrangement 18 for measuring the flow of a medium flowing through the measuring tube 17, with at least one receiving unit 16 for a sensor unit 2 and with a sensor unit 2 arranged in the receiving unit 16. The printed circuit board 5 of the sensor unit 2 has further functional areas in addition to the connection to the carrier 6. In detail, the printed circuit board is also connected to the measuring arrangement 18 for measuring the flow with functional areas 22 and also has connectors 21 for the supply and/or communication of the measuring arrangement and/or the sensor.

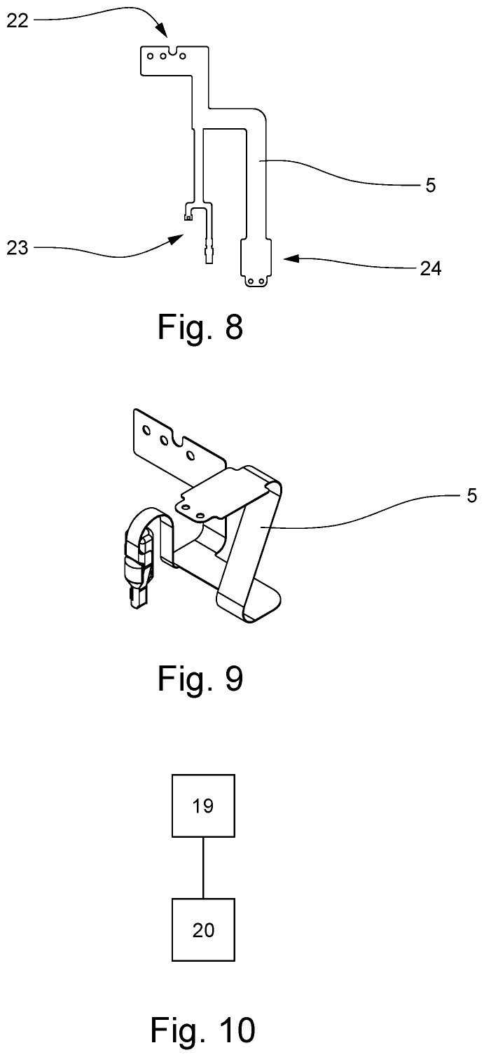

FIG. 8 shows an embodiment of a printed circuit board 5 according to the invention, wherein the printed circuit board 5 has several functional subsections. A first subsection 23 is used for connection to the carrier 6, a second subsection 22 is used for connection to the measuring arrangement 18 to measure the flow through the measuring tube and a third subsection 24 is used for supply and/or communication of the measuring arrangement 18 and/or the sensor 4. Using advantageous bending of the printed circuit board 5, all functional subsections can be arranged at the position intended for connection.

FIG. 9 shows an embodiment of the sensor unit 2 in the bent state, wherein the printed circuit board 5 is at least partially wrapped around the carrier.

FIG. 10 shows a first embodiment of a method 3 according to the invention for manufacturing, in detail for mounting a flowmeter 1, wherein the flowmeter 1 is designed according to the embodiment shown in FIG. 7.

In a first step 19, the flexible printed circuit board 5 is at least partially folded around the carrier 6 and fixed to it.

Then the sensor unit 2 is inserted 20 into the receiving unit 16 so that the sensor 4 is located inside the measuring tube 17. At the same time the additional functional subsections 22 and 24 are positioned intended for their connection.

The installation of the sensor 4 is therefore particularly easy. In addition, the sensor unit can also be replaced very easily.

1. A flowmeter, comprising:
at least one measuring tube;
a measuring arrangement for measuring the flow of a medium flowing through the measuring tube;
at least one receiving unit for a sensor unit; and
a sensor unit;
wherein the receiving unit is arranged on the measuring tube;
wherein the sensor unit includes at least one sensor, at least one flexible printed circuit board and at least one carrier;
wherein the at least one sensor is arranged on the at least one flexible printed circuit board;
wherein the sensor unit is plugged into the receiving unit; and
wherein the at least one flexible printed circuit board is at least partially wrapped or folded around the carrier such that the sensor is arranged inside the measuring tube in the inserted state.

2. The flowmeter according to claim 1, wherein the receiving unit is cup-shaped and the carrier of the sensor unit is at least partially plug-shaped so that the carrier closes the cup-shaped receiving unit as a plug.

3. The flowmeter according to claim 1, wherein the at least one sensor is a temperature sensor and/or a pressure sensor and/or a conductivity sensor.

4. The flowmeter according to claim 1, wherein the flexible printed circuit board is a bendable printed circuit board.

5. The flowmeter according to claim 1, wherein the flexible printed circuit board encloses the carrier at least partially in the longitudinal direction and/or at least partially transverse to the longitudinal direction.

6. The flowmeter according to claim 1, wherein the carrier has at least one recess and the flexible printed circuit board has at least one first connection area;
wherein the shape of the recess substantially corresponds to the shape of the first connection area; and
wherein the flexible printed circuit board is placed with the connection area into the at least one recess.

7. The flowmeter according to claim 1, wherein the carrier has at least one fixing element for fixing the printed circuit board to the carrier.

8. The flowmeter according to claim 7, wherein the at least one fixing element is a slot and/or a groove and/or a seam and/or a chamfer and/or an edge projecting beyond the printed circuit board.

9. The flowmeter according to claim 1, wherein the flexible printed circuit board has at least one mounting element; and
wherein the at least one mounting element is preferably in operative connection with the at least one fixing element.

10. The flowmeter according to claim 1, wherein a ground connection is arranged on the flexible printed circuit board and that the ground connection is connected to the housing of the flowmeter.

11. The flowmeter according to claim 1, wherein the flexible printed circuit board has several functional subsections;
wherein the functional subsections are arranged on different arms of the flexible printed circuit board, such that the functional subsections are positioned at the point of their connection by separately bending of the arms.

12. The flowmeter according to claim 1, wherein an insulation element and/or a heat conduction element is arranged on the sensor.

13. The flowmeter according to claim 1, wherein the sensor unit is held positively and/or non-positively in the receiving unit.

14. A sensor unit for installation in a flowmeter, wherein the flowmeter includes at least one measuring tube, a measuring arrangement for measuring the flow of a medium flowing through the measuring tube, and at least one receiving unit arranged on the measuring tube for receiving the sensor unit, the sensor unit comprising:
at least one sensor;
at least one flexible printed circuit board; and
at least one carrier;
wherein the at least one sensor is arranged on the at least one flexible printed circuit board; and
wherein the at least one flexible printed circuit board is at least partially wrapped or folded around the carrier.

15. The sensor unit according to claim 14, wherein the receiving unit of the flowmeter is cup-shaped; and
wherein the at least one carrier of the sensor unit is at least partially plug-shaped so that the carrier closes the cup-shaped receiving unit as a plug.

16. A method for manufacturing a flowmeter, wherein the flowmeter includes at least one measuring tube, a measuring arrangement for measuring the flow of a medium flowing through the measuring tube, at least one receiving unit for a sensor unit, and a sensor unit, wherein the receiving unit is arranged on the measuring tube, wherein the sensor unit includes at least one sensor, at least one flexible printed circuit board and at least one carrier, wherein the at least one sensor is arranged on the at least one flexible printed circuit board, wherein the sensor unit is plugged into the receiving unit, and wherein the at least one flexible printed circuit board is at least partially wrapped or folded around the carrier such that the sensor is arranged inside the measuring tube in the inserted state, the method comprising:
wrapping and/or folding the at least one flexible printed circuit board at least partially around the carrier; and
plugging the sensor unit into the receiving unit so that the sensor is arranged inside the measuring tube.

17. The sensor unit according to claim 14, wherein the flexible printed circuit board is a bendable printed circuit board.

18. The sensor unit according to claim 14, wherein the flexible printed circuit board encloses the carrier at least partially in the longitudinal direction and/or at least partially transverse to the longitudinal direction.

19. The sensor unit according to claim 14, wherein the carrier has at least one recess and the flexible printed circuit board has at least one first connection area;
wherein the shape of the recess substantially corresponds to the shape of the first connection area; and
wherein the flexible printed circuit board is placed with the connection area into the at least one recess.

20. The sensor unit according to claim 14, wherein the carrier has at least one fixing element for fixing the printed circuit board to the carrier.
